(19) United States
(12) Patent Application Publication
(10) Pub. No.: US 2007/0170934 A1
(43) Pub. Date: Jul. 26, 2007

(54) Method and Apparatus for Nondestructive Evaluation of Semiconductor Wafers

(75) Inventor: Xianyun Ma, Lexington, SC (US)

Correspondence Address: XIANYUN MA, 428 BUCKHOME DR., LEXINGTON, SC, 29072, US

(73) Assignee: MAXMILE TECHNOLOGIES, LLC, Lexington, SC (US)

(21) Appl. No.: 11/307,084

(22) Filed: Jan. 23, 2006

(51) Int. Cl. G01R 31/02

(52) U.S. Cl. 324/754

(57) ABSTRACT

An evaluation apparatus is taught to nondestructively characterize the material that can be any type of any semiconductor or dielectric materials, or a coating or film deposit on the semiconductor wafer. An electrode probe is used to temporarily form a Schottky or metal oxide semiconductor (MOS) device through forming an intimate electrical contact to the surface of the material. A testing system is provided for applying an electrical stimulus to the temporarily formed device through the electrode probe, and for measuring the response to the electrical stimulus. Various properties of the material can be nondestructively determined from the measured response.

### FIELD OF THE INVENTION

This invention relates generally to a method and apparatus for evaluating the electrical properties of a semiconductor or dielectric wafer, or a coating or film deposited on a semiconductor wafer. In particular, the present invention teaches the method and apparatus for evaluating semiconductor wafers in a nondestructive manner.

### DESCRIPTION OF RELATED ART

In the research and development or production of semiconductor materials, it is important to determine the electrical properties of the materials. Various electrical measurements based on capacitance-voltage (CV) and current-voltage (IV) techniques, such as measurements of threshold voltage, doping profile, leakage current and breakdown strength, have been developed; however these measurements are usually accomplished by first fabricating devices, typically Schottky contact or metal oxide semiconductor (MOS) structures, on the top of the semiconductor wafer. Fabrication of devices is time-consuming and costly; and the fabricated devices become permanent features on semiconductor wafer which make the entire wafer unfit for normal use. Therefore, these measurements are usually performed on monitor or test wafers. As semiconductor technology marches into a new era, various new material systems like wide-band gap semiconductors for next generation power electronics and lighting have been being developed. These materials are expensive and much more complicated in material structure, which post a strong need for more advanced characterization techniques. From the research and manufacturing point of view, nondestructive electrical characterization approaches are highly needed for the development of semiconductor materials and devices.

In current standard practice, a mercury probe has been frequently used for nondestructive electrical evaluation of semiconductor wafers. The mercury contact is formed by mercury contacting the semiconductor wafer through a well-defined orifice, with the orifice opening defining the device area. Usually the semiconductor surface should be treated before the mercury contacts the surface for reproducible measurements. At times it is necessary to achieve a stable surface by growing a thin oxide on the wafer to realize a low leakage current Schottky contact.

However, there are a lot of limitations in using the mercury probe. Mercury is the only metal which is liquid at room temperature. Mercury probe works because of this unique property. On the other hand, due to the liquid state property, the design of mercury probe is complicated and it is difficult to realize more sophisticated probe structures. Usually a vacuum system is also used to drive the mercury which would further complicate the use of the probe. Though the mercury contact appears to neither damage the silicon (Si) wafer nor leave mercury on the surface, Si wafers measured with a mercury probe are usually not used for device processing. The possibility exists that mercury may react chemically with the materials of new semiconductor wafers under study. Due to the high surface tension of mercury, a micrometric gap, hence a triple junction structure (metal-air-semiconductor), would form in the place where the mercury and semiconductor contact, especially when the mercury contact area is relatively large and the surface of semiconductor wafer is not very smooth. The electrical field in the triple junction is greatly enhanced which could lead to a catastrophic damage to the material under test. Mercury sublimes especially at the elevated temperature environment when accelerated temperature testing of the semiconductor is requested. Vacuum-driven mercury probe would further enhance the sublimation of mercury. Due to its cumulative poisonous nature, the use of mercury poses a significant safety issue.

It is, therefore, an objective of the present invention to overcome the above problems by providing an alternative nondestructive electrical characterization method and apparatus that enables improved electrical measurements of semiconductor wafers. The present invention will also introduce several unique electrical characterization techniques for new semiconductor material systems which have been under development.

### SUMMARY OF THE INVENTION

In accordance with one aspect of the present invention, a nondestructive electrode probe is disclosed. With this probe, a device, either Schottky contact or metal oxide semiconductor (MOS) structure, will be temporarily formed in the semiconductor wafer through a well-defined electrical contact, with the contact defining the device area. The formed device is nondestructive, instant, and can be used for wafer-level and micrometric-scale investigations on semiconductor wafers. With a means for applying an electrical stimulus to the probe and a means for measuring the electrical response, various electrical properties of the material can be characterized nondestructively at the wafer level. The semiconductor wafer can be any type of semiconductor or dielectric materials, or a coating or film deposited on the semiconductor wafer.

Preferably, spring loaded contact probes, or other similar means, will be used as electrodes in the disclosed electrode probes with which the force of electrodes on the material can be properly controlled to avoid possible mechanical damage to the tested material. The tip of electrodes is preferably made from an elastically-deformable electrically-conductive material and has flat surface with well-defined contact area. Together with means for controlling the electrode force, the elastically-deformable electrically-conductive material is used to ensure that an intimate contact between the electrodes and the semiconductor is formed and the area of temporary device is well-defined. Preferably, a concentric dot and ring electrodes, which are also made from an elastically-deformable electrically-conductive material, are used in the disclosed electrode probe.

In accordance with another aspect of the present invention, an apparatus for evaluating the semiconductor wafer is disclosed. The apparatus is developed based on the disclosed electrode probe. With a means for applying an electrical stimulus in the probe and a means for measuring the electrical response, the electrical properties of semiconductor materials can be nondestructively evaluated. The advantage of the present invention is that some evaluation can be done at the wafer level in terms of finished device performance.

Preferably, the apparatus includes a translation means for relatively translating the electrode probe and the semiconductor wafer. The translation stage can be controlled at wafer-level or micrometric scale. With a scanning stage, the above evaluations can be used to determine the wafer-level uniformity of the electrical properties of semiconductor wafers. The micrometric-scale scanning capability could be used for localized investigations which include defect influences on device performance.

In accordance with yet another aspect of the present invention, using the disclosed electrode probe, methods for characterizing various semiconductor materials are disclosed. The disclosed probe will find its applications in various electrical measurements based on conventional capacitance-voltage (CV) and current-voltage (IV) techniques, as well as the electrical measurements under the stimulus of temperature, optical, magnetic field, or the like. Specific nondestructive characterization techniques for wide-band gap semiconductor material (SiC and GaN) will be further disclosed.

### BRIEF DESCRIPTION OF THE DRAWINGS

The invention may take forms in various components and arrangements of components, and various steps and arrangements of steps. The drawings are only for the purposes of illustrating a preferred embodiment and are not to be constructed as limiting the invention.

FIG. 1 is a schematic illustration of one embodiment of a nondestructive electrode probe.

FIG. 2 is a schematic drawing of one embodiment of electrode arrangement (hexagonal) used in FIG. 1.

FIG. 3 is a schematic drawing of one embodiment of electrode arrangement (concentric) used in FIG. 1.

FIG. 4 is a schematic illustration of one embodiment of a nondestructive electrode probe with enhanced electrical contacts.

FIG. 5 is the experimental results of a silicon carbide sample indicating Schottky characteristics.

FIG. 6 is the experimental results of a gallium nitride sample indicating Schottky characteristics.

FIG. 7 is a schematic illustration of one embodiment of a nondestructive evaluation apparatus using disclosed electrode probes.

### DETAILED DESCRIPTION OF THE INVENTION

The present invention will be described with the reference to the accompanying figures wherein like reference numbers correspond to like elements.

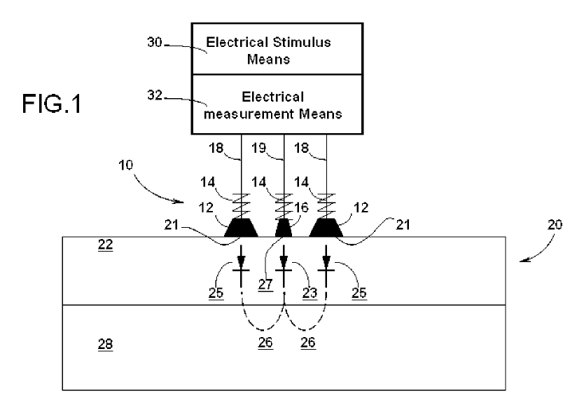

With reference to FIG. 1, a semiconductor wafer testing method is described in accordance with one embodiment of a nondestructive electrode probe. The electrode probe 10 operates upon an associated semiconductor sample 20. In FIG. 1, the associated sample 20 is silicon carbide (SiC) epitaxial wafer which has n-type highly doped SiC substrate 28 with n-type SiC epitaxial thin film 22 deposited on the substrate 28. The SiC epitaxial film 22 is the active layer which is typically used for fabricating Schottky device. Certainly, the invention is not limited in application to the exemplary n-type SiC epitaxial wafer shown in FIG. 1, the associated sample 20 can be any type of any semiconductor or dielectric materials, or a coating or film deposited on the semiconductor wafer.

With continuing reference to FIG. 1, the nondestructive electrode probe 10 consists of electrodes 12 and 16 with well-defined contact area 21 and 27. Electrodes 12 and 16 are used to temporarily form electrical contacts 21 and 27 to the surface of associated sample 20. Well-defined Schottky devices 25 and 23 are simultaneously formed in the active layer at the places right below the contacts 21 and 27 correspondingly. Preferably, the force of electrodes on the material is properly controlled to avoid the possible mechanical damage to the tested material. One exemplary approach to control the electrode force is to use spring 14 loaded electrodes 12 and 16. Though metal probes, such as commercially available pogo probes, can be used in the present invention, the tip of electrodes 12, 16 is preferably made from an elastically-deformable electrically-conductive material and has flat surface with well-defined contact area. Together with means for controlling the electrode force, the elastically-deformable electrically-conductive material is used to ensure that intimate contacts 21 and 27 are formed between the electrodes and the semiconductor material and the area of the temporary Schottky devices 23 and 25 is well-defined. The elastically-deformable electrically-conductive material can be a conductive elastomer or a conductive polymer, or the like.

With ongoing reference to FIG. 1, a proper electrical stimulus will be applied between electrodes 16 and 12 by the electrical stimulus means 30. The electrical stimulus can be DC current or voltage, AC voltage combined with a DC bias voltage, AC voltage, or the like. The stimulus will be different for different electrical measurement purposes and different type of semiconductor materials. In the exemplary n-type SiC epitaxial wafer 20 drawn in FIG. 1, Schottky devices 23 and 25 is oriented positively from the contacts 27 and 21 to the SiC epitaxial film, while the negative ends 26 of Schottky device 23 and 25 are connected to each other through the n-type highly doped SiC substrate 28. In order to realize a capacitance doping profile measurement based on conventional CV technique in FIG. 1, it is requested that the Schottky device 23 will be reverse biased with superimposition of a small-amplitude ac voltage. This condition can be realized through applying a reverse bias with superimposition of a small-amplitude ac voltage directly between electrodes 16 and 12. Under this condition, the Schottky device 25 will be forward biased, and the voltage drop on Schottky device 25 will be relatively small and constant. Correspondingly the reverse bias with superimposition of a small-amplitude ac voltage applied between electrodes 16 and 12 will be mainly dropped on Schottky device 23; therefore a capacitance doping profile measurement can be realized through the disclosed electrode probe shown in FIG. 1. Generally speaking, the electrical measurement means 32 measures the electrical response to the applied electrical stimulus through the electrical stimulus means 30, and determines from the response one or more electrical properties of the test sample 20.

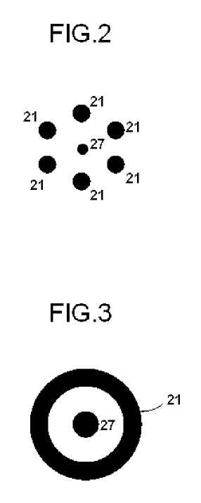

With continuing reference to FIG. 1, and with further reference to FIGS. 2-3, the electrode 12 preferably consists of multiple contact points 21 which uniformly surround the electrical contact 27. Though FIG. 2 shows one embodiment of electrode 12 arrangement with six contact points 21, the invention is not limited in application to this embodiment. The number of contact points 21 can be any number starting from one. The contact shapes are not necessarily the circular as shown in FIGS. 2 and 3, any other shapes, such as triangular, rectangular, square, pentagon, and the like, can be used. Though the size of contact 27 is preferably smaller than the size of contact 21, they are not necessarily the same. Preferably, a concentric dot 27 and ring 21 structure are used for electrodes 16 and 12 respectively. The concentric dot 27 and ring 21 electrodes (as shown in FIG. 3) are also preferably made from an elastically-deformable electrically-conductive material such as a conductive elastomer or a conductive polymer. The dimensions for contacts 21, 27 of these electrodes can be of any size, from a few microns to a few centimeters, or even bigger, which should be determined by the purpose of the specific measurement application. For the purpose of high scanning resolution, a smaller contact size of electrodes is preferred.

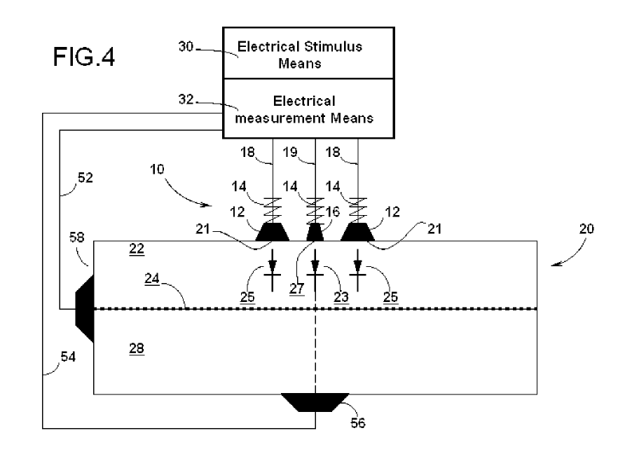

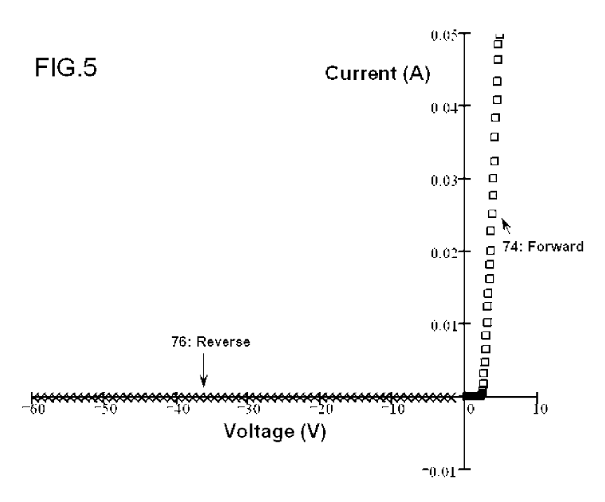

With continuing reference to FIG. 1, and with further reference to FIG. 4, the nondestructive electrode probe shown in FIG. 1 can be further enhanced with a third electrode which is configured differently according to the different material structures as shown in FIG. 4. The substrate 28 in different semiconductor material systems can be identified as conductive or nonconductive/insulated. For example, sapphire substrates and insulated SiC substrates for GaN-based transistor application are nonconductive/insulated; while the n-type highly doped SiC substrates for SiC-based Schottky diode application are conductive. (1) For the material systems with conductive substrate, the negative ends 26 of Schottky device 23 and the substrate 28 are usually electrically connected. A third electrode 56, which is connected electrically to the substrate, is preferably used. Under this test setup, the electrical stimulus will pass through the loop formed by electrical wire 19, electrode 16, contact 27, temporary Schottky device 23, conductive substrate 28, electrode 56, and electrical wire 54. The electrode 12 can be used as guard ring configuration to reduce the noise and possible current leakage. The use of guard ring configuration of the electrode 12 is straightforward and known in the art. Under this electrode configuration, a proper electrical stimulus will be applied between electrodes 16 and 56 by the electrical stimulus means 30. For a capacitance doping profile measurement on semiconductor like n-type SiC epitaxial thin film 22 deposited on the substrate 28, a reverse bias with superimposition of a small-amplitude ac voltage is applied between electrodes 16 and 56. (2) When the substrate of the material systems is insulated, a highly conductive layer 24 is usually sandwiched between the layer 22 and the substrate 28. If this is the case, the third electrode 58 can be used to electrically connect the conductive layer 24 at the edge of the wafer. Correspondingly, under this test setup, the electrical stimulus will pass through the loop formed by electrical wire 19, electrode 16, contact 27, temporary Schottky device 23, conductive layer 24, electrode 58, and electrical wire 52. Again, the electrode 12 can be used as guard ring configuration to reduce the noise and possible current leakage. Under this electrode configuration, a proper electrical stimulus will be applied between electrodes 16 and 58 by the electrical stimulus means 30. Though only one contact for electrodes 56 or 58 is drawn in FIG. 4, the electrodes 56 or 58 preferably are multiple contact points or with large area. To ensure a good electrical contact, the electrodes 58 and 56 are preferably made from an elastically-deformable electrically-conductive material such as a conductive elastomer, or a conductive polymer, or a metal sheet with conductive adhesive. The advantage of using the third electrode 56 or 58 in the present invention is that, besides it uses a smaller electrical stimulus, the current-voltage characteristics of the semiconductor wafer and the electrical properties of conductive layer 24 can be further determined at the wafer level as the finished device functions.

With continuing reference to FIGS. 1 and 4, and with further reference to FIG. 5, a typical Schottky current-voltage (IV) characteristic is shown in FIG. 5, which was taken from a n-type SiC epitaxial thin film 22 deposited on the substrate 28 by the disclosed electrode probe as shown in FIG. 4. SiC is the promising wide-band gap semiconductor material for high-power, high-temperature, high frequency power electronic applications. The IV characteristic shown in FIG. 5 indicates that, using the disclosed electrical probes, the electrical properties of semiconductor materials can be determined at the wafer level directly in terms of finished Schottky device performance. With such capability, various electrical properties can be nondestructively determined from CV or IV measurement using disclosed electrode probes. For example, based on the IV characteristics shown in FIG. 5, the doping profile, breakdown strength, Schottky barrier height, etc of n-type SiC epitaxial film can be nondestructively measured at reverse 76 and forward 74 bias regimes respectively. The CV or IV measurements using disclosed probe are similar to the conventional ones performed on the finished device and are well-known in the art.

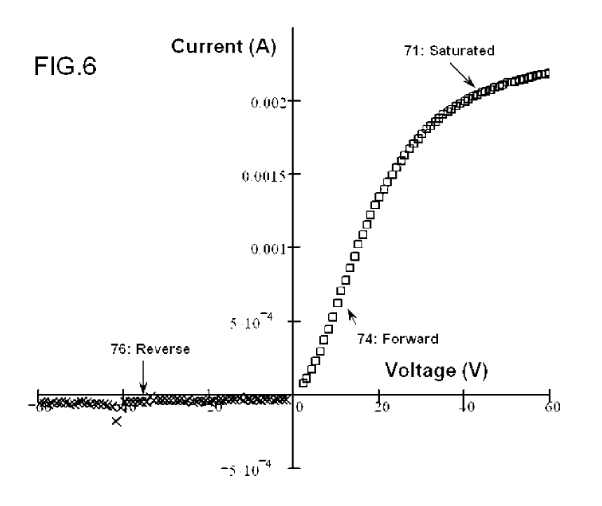

With continuing reference to FIGS. 1 and 4, and with further reference to FIG. 6, a unique characterization technique is described, using the disclosed electrical probes, to evaluate the electrical properties of two-dimensional electron gas (2DEG) layer in AlGaN/GaN material systems. The wide band-gap GaN material system holds great promise for high frequency, high temperature, and high power electronic devices due to its high mobility, high breakdown field, and high saturation electron velocity. The application of AlGaN/GaN heterostructure improves the material quality greatly with the strong screening of ionized impurities and other scattering centers by the high density of the 2DEG. The existence of 2DEG and detection/evaluation of 2DEG would play a key role in developing the applications based on AlGaN/GaN heterostructure. FIG. 6 shows a typical Schottky current-voltage (IV) characteristic which is taken from a typical AlGaN/GaN heterostructure sample using the disclosed electrode probe as shown in FIG. 4. Based the formation of Schottky contact to the AlGaN/GaN heterostructure material, various properties of the material can be nondestructively determined using conventional CV or IV measurement through the disclosed electrode probe at different working regimes (reverse, forward or saturated bias). The determined properties of the AlGaN/GaN material include film thickness, the 2DEG sheet carrier density and width, pinch-off voltage, breakdown strength, etc.

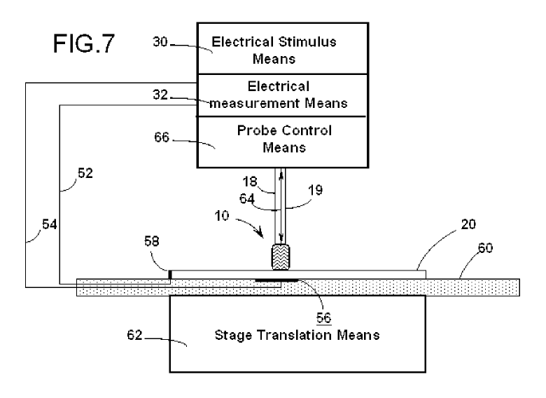

With continuing reference to FIGS. 1-4, and with further reference to FIG. 7, an apparatus embodiment is shown in FIG. 7. The apparatus consists of the above disclosed nondestructive electrode probe 10, electrical stimulus means 30, electrical measurement means 32, probe control means 66, sample stage 60 and preferably the stage translation means 62. The probe control means 66 is used to load and unload the nondestructive electrode probe 10 to form the well-defined device in the sample 20; it will also control the contact force of electrodes to avoid possible mechanical damages to the sample 20. Sample stage 60 provides the place to hold sample and will also have the means to produce good electrical contacts for electrodes 58 and 56.

Preferably, the associated sample 20 is mounted on the stage 60 which is driven by a stage translation means 62. The sample 20 can be moved laterally with respect to the electrode probe 10. In this way, the lateral inhomogeneities of various properties of the sample 20 can be probed.

This invention relates generally to a method and apparatus for evaluating the electrical properties of semiconductor materials. Though the above description revealed the specific applications related to SiC and GaN based material systems, the invention is not limited so in applications, the associated sample 20 can be any type of any semiconductor or dielectric materials, or a coating or film deposit on a semiconductor wafer. The formed device is also not limited to forming Schottky device; ohmic contact or metal oxide semiconductor (MOS) structure can also be formed. The MOS structure is typically on the surface of dielectric film deposited on semiconductor wafer. Correspondingly, conventional electrical measurements based on MOS structure can also be nondestructively realized through the disclosed electrode probes. Furthermore, together with electrical stimulus, the disclosed electrodes and measurement techniques can be used broadly for the measurements under additional stimulus of temperature, optical, magnetic field, or the like.

The invention has been described with reference to the preferred embodiments. Obviously, modifications and alterations will occur to others upon reading and understanding the preceding detailed descriptions. It is intended that the invention be constructed as including all such modifications and alterations insofar as they come within the scope of appended claims or the equivalents thereof.

What is claimed is:

1. A electrode probe for evaluating semiconductor material through temporarily forming Schottky or metal oxide semiconductor (MOS) devices in the material, said material being of any type of any semiconductor or dielectric materials, or a coating or film deposited on a semiconductor wafer, the electrode probe comprising:
two electrodes contacting the surface of said material through a well-defined electrical contact, with said contact defining said device area;
means for controlling the force of said electrodes on said material to avoid the possible mechanical damage to said material;
means for applying a test stimulus between the electrode probe and said material;
means for measuring the electrical response of said material to the test stimulus.

2. The electrode probe as recited in claim 1, wherein said means for controlling the force of electrodes on said material is the spring loaded electrodes.

3. The electrode probe as recited in claim 1, wherein the tips of said electrodes are made from an elastically-deformable electrically-conductive material and have well-defined contact area so that an intimate contact and well defined device area are formed. The said elastically-deformable electrically-conductive material can be a conductive elastomer or a conductive polymer, or the like.

4. The electrode probe as recited in claim 1, wherein one of said electrodes consists of multiple electrical contact points which uniformly surround the other electrode of said electrodes.

5. The electrode probe as recited in claim 1, wherein said electrodes are concentric dot and ring electrodes which are preferably made from an elastically-deformable electrically-conductive material.

6. The electrode probe as recited in claim 1, wherein said probe is enhanced with a third electrode which is electrically connected (i) at the edge when said material has insulated substrate, or (ii) the substrate when said material has conductive substrate.

7. The electrode probe as recited in claim 6, wherein said third probe is made from elastically-deformable electrically-conductive material or has multiple contact points.

8. An apparatus for nondestructively evaluating semiconductor material through temporarily forming Schottky or MOS devices in the material, said material being of any type of any semiconductor or dielectric materials, or a coating or film deposit on the semiconductor wafer, the apparatus comprising:
two electrodes temporarily forming an intimate contact to the surface of said material through a well-defined electrical contact, and with said contact defining said device area;
a sample stage for supporting said semiconductor material;
means for loading/unloading said electrodes and controlling the force of said electrodes on said material to avoid the possible mechanical damage to said material;
means for applying a electrical stimulus to said devices;
means for measuring the electrical response of said material to the electrical stimulus.

9. The apparatus as recited in claim 8, wherein said sample stage has means to provide an electrical contact to (i) the edge of the semiconductor material when said material has insulated substrate, or (ii) the substrate when said material has conductive substrate.

10. The apparatus as recited in claim 8, wherein said sample stage is driven by a stage translation means so that said material under evaluation can be moved laterally with respect to the electrodes and lateral inhomogeneities evaluation can be performed.

11. A method of nondestructively evaluating semiconductor material, said material being of any type of any semiconductor or dielectric materials, or a coating or film deposit on the semiconductor wafer, the method comprising the steps of:
providing electrodes temporarily forming intimate electrical contacts to the surface of said material;
forming a first electrical contact to said material and temporarily forming a well-defined Schottky of MOS device in the material;
forming a second electrical contact to (i) the surface of the material with a ring-structured or multiple-points electrical contact which uniformly surround the first electrical contact, or (ii) the edge of the semiconductor material if said material has insulated substrate, or (iii) the substrate if said material has conductive substrate;
applying an electrical stimulus between the first electrical contact and the second electrical contact;
measuring electrical response to the electrical stimulus, and
determining from the response various properties of the semiconductor material at different working regime.

12. The method as recited in claim 11, wherein said sample stage is driven by a stage translation means so that the material under evaluation can be moved laterally with respect to the electrodes and lateral inhomogeneities evaluation can be performed.

13. The method as recited in claim 11, wherein said sample is SiC-based material system, through testing the Schottky characteristics of material, the doping profile, breakdown strength, Schottky barrier height, etc will be nondestructively determined.

14. The method as recited in claim 11, wherein said sample is GaN-based material system, through testing the Schottky characteristics of material, the film thickness, two-dimensional electron gas sheet carrier density and width, pinch-off voltage, breakdown strength, etc of the material will be nondestructively determined.
